(19) United States
(12) Patent Application Publication
(10) Pub. No.: US 2019/0228952 A1
(43) Pub. Date: Jul. 25, 2019

(54) PROCESSING WITH POWERED EDGE RING

(71) Applicant: Applied Materials, Inc., Santa Clara, CA (US)

(72) Inventors: Leonid DORF, Santa Clara, CA (US); Anurag Kumar MISHRA, Fremont, CA (US); Olivier LUERE, Sunnyvale, CA (US); Rajinder DHINDSA, Pleasanton, CA (US); James ROGERS, Los Gatos, CA (US); Denis M. KOOSAU, Pleasanton, CA (US); Sunil SRINIVASAN, Milpitas, CA (US)

(21) Appl. No.: 16/253,655

(22) Filed: Jan. 22, 2019

Related U.S. Application Data
(60) Provisional application No. 62/620,415, filed on Jan. 22, 2018.

(51) Int. Cl. H01J 37/32; H01L 21/683; H01L 21/3065; H01L 21/67

(52) U.S. Cl. CPC H01J 37/32642; H01L 21/6833; H01J 37/32091; H01J 2237/3341; H01L 21/3065; H01L 21/67069; H01J 37/32715; H01J 37/32146

(57) ABSTRACT

Embodiments of the present disclosure generally relate to methods and related process equipment for forming structures on substrates, such as etching high aspect ratio structures within one or more layers formed over a substrate. The methods and related equipment described herein can improve the formation of the structures on substrates by controlling the curvature of the plasma-sheath boundary near the periphery of the substrate, for example, by generating a substantially flat plasma-sheath boundary over the entire substrate (i.e., center to edge). The methods and related equipment described below can provide control over the curvature of the plasma-sheath boundary, including generation of the flat plasma-sheath boundary by applying RF power to an edge ring surrounding the substrate using a separate and independent RF power source.

### CROSS-REFERENCE TO RELATED APPLICATIONS

This application claims benefit of U.S. provisional patent application Ser. No. 62/620,415, filed Jan. 22, 2018, which is hereby incorporated herein by reference.

### BACKGROUND

### Field

Embodiments of the present disclosure generally relate to methods for forming structures on substrates, such as high aspect ratio structures for forming semiconductor devices.

### Description of the Related Art

A Reactive Ion Etch (RIE) is used to remove portions of layers for creating structures on substrates, such as high aspect ratio structures for forming semiconductor devices. A substrate is typically placed on an electrostatic chuck (ESC) in a process chamber, and an RF voltage is applied to a conductive element disposed within the electrostatic chuck assembly to generate a plasma over the substrate. RF power may also be applied to one or more inductive coils disposed on top of the process chamber for generating the plasma. The substrate is often surrounded by an edge ring that can be used to couple the RF energy supplied to the ESC to regions in the process chamber above the edge ring to provide control over the curvature of the plasma-sheath boundary near the periphery of the substrate. Despite the use of edge rings, obtaining uniform RIE results across an entire substrate remains a challenge. For example, even with the use of edge rings, etching rates can vary between locations at the center of a substrate and the edge of a substrate. Furthermore, the shape of features (e.g., high aspect ratio structures) created at the center of the substrate can differ from the shape of features created at the edge of the substrate as a result of an RIE process. These variable etch rates and feature shapes produced by RIE prevent uniform results from being obtained and can lead to variations in device performance for die formed at different locations on the surface of the substrate.

Therefore, an improved RIE process and related equipment are needed to produce more uniform etching results across processed substrates, for example from a center of a substrate to the edges of the substrate.

### SUMMARY

Embodiments of the present disclosure generally relate to methods and related process equipment for forming structures on substrates, such as etching high aspect ratio structures within one or more layers formed over a substrate. In one embodiment, a substrate support assembly is provided. The substrate support assembly includes an electrostatic chuck assembly comprising an electrode, wherein the electrode is electrically connected to a first RF power source; an edge ring disposed around the electrostatic chuck assembly; and a distributor attached to a surface of the edge ring, wherein the distributor is directly connected to a second RF power source.

In another embodiment, a plasma processing system is provided. The plasma processing system includes an RF power source assembly comprising: a first RF power source; and a second RF power source; and a substrate support assembly, comprising; an electrostatic chuck assembly comprising an electrode, wherein the electrode is electrically connected to the first RF power source; and an edge ring disposed around the electrostatic chuck assembly, wherein the edge ring is electrically connected to the second RF power source.

In another embodiment, a method of processing a substrate is provided. The method includes supplying one or more gases to a process volume of a plasma chamber, wherein a first electrode is positioned to provide electromagnetic energy to the process volume when RF power is provided to the first electrode; a first substrate is disposed on an electrostatic chuck assembly that is disposed within the process volume, the electrostatic chuck assembly includes an electrode, and an edge ring is disposed around the electrostatic chuck assembly; generating a plasma of the one or more gases in the process volume of the plasma chamber by energizing a first RF power source electrically connected to the first electrode; and etching a portion of the first substrate by energizing a second RF power source electrically connected to the edge ring and energizing a third RF power source electrically connected to the electrode of the electrostatic chuck assembly after generating the plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of the scope, for the disclosure may admit to other equally effective embodiments.

FIG. 1A is a partial cross-sectional view of a first device substrate disposed on an electrostatic chuck (ESC) and being processed by a plasma during plasma processing.

FIG. 1B shows a cross-sectional view of a region of the first device substrate of FIG. 1A.

FIG. 1C is a partial cross-sectional view of a second device substrate disposed on the electrostatic chuck and being processed by a plasma during plasma processing.

FIG. 1D shows a cross-sectional view of a region of the second device substrate of FIG. 1C.

FIG. 1E is a plot illustrating the effect of adjusting the sheath voltage radial profile on normalized etch rate versus radial position on a substrate.

FIG. 1F is a plot illustrating the effect of adjusting the sheath voltage radial profile on normalized critical dimension (CD) bias versus radial position on a substrate.

FIG. 2A is a simplified cutaway view for an exemplary etching process system including an etching process chamber for performing a plasma process, according to one embodiment.

FIG. 2B is a top view of the device of FIG. 2A disposed on the ESC and surrounded by an edge ring assembly of FIG. 2A, according to one embodiment.

FIG. 2C is a partial cross-sectional view of the device, the ESC, and the edge ring assembly taken along section line 2C of FIG. 2B, according to one embodiment.

FIG. 2D illustrates an RF power delivery timing sequence that may be used during processing, according to one embodiment.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

Embodiments of the present disclosure generally relate to methods and related process equipment for forming structures on substrates, such as etching high aspect ratio structures within one or more layers formed over a substrate. The methods and related equipment described below can improve the formation of the structures on substrates by controlling the curvature of the plasma-sheath boundary near the periphery of the substrate, for example, by generating a substantially flat plasma-sheath boundary over the entire substrate (i.e., center to edge). The methods and related equipment described below can provide control over the curvature of the plasma-sheath boundary, including generation of the flat plasma-sheath boundary, by independently controlling the RF power applied to an edge ring surrounding the substrate. Although the following disclosure describes methods of applying RF power to an edge ring disposed within an inductively coupled plasma processing chamber, the disclosure is equally applicable to any process chamber configuration that includes an inductively or capacitively coupled process chamber plasma source.

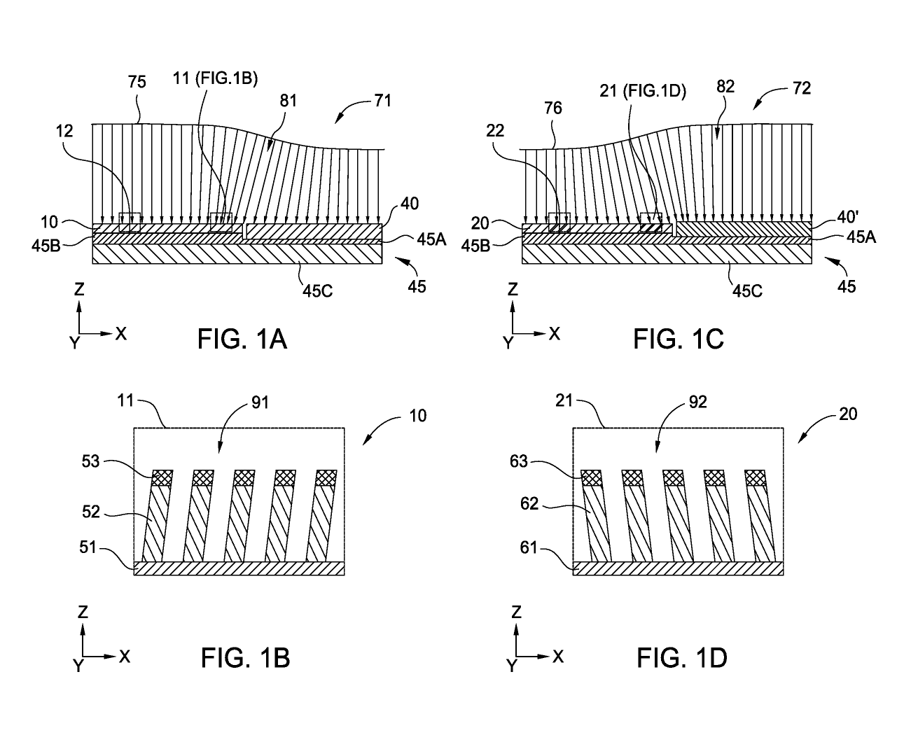

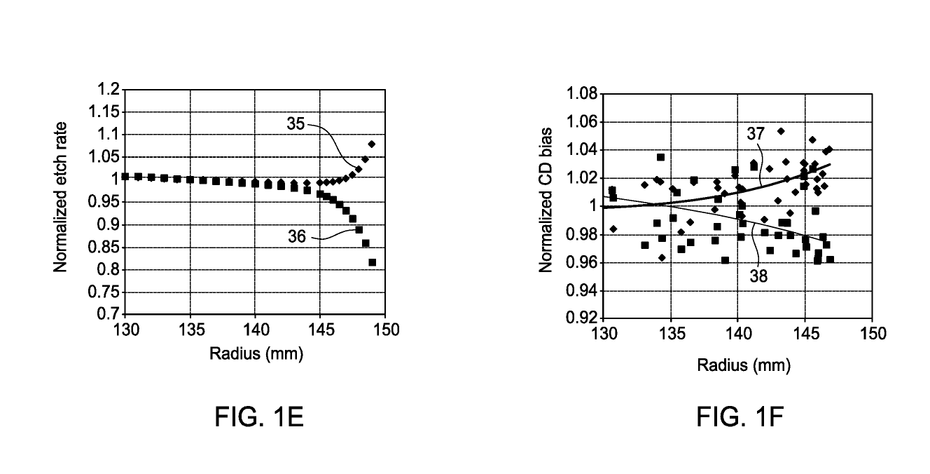

A typical Reactive Ion Etch (RIE) plasma processing chamber includes a radio frequency (RF) bias generator, which supplies an RF voltage to a “power electrode”, which can be a metal baseplate embedded within the “electrostatic chuck” (ESC) assembly, more commonly referred to as the “cathode”. The power electrode is capacitively coupled to the plasma of a processing system through a layer of ceramic, which is a part of the ESC assembly. Non-linear, diode-like nature of the plasma sheath results in rectification of the applied RF field, such that a direct-current (DC) voltage drop, or “self-bias”, appears between the cathode and the plasma. This voltage drop across the sheath (or “sheath voltage”) determines the average energy of the plasma ions accelerated towards the cathode, as well as the average sheath thickness (according to the Child-Langmuir Law, in zeroth order approximation). The electric field in the sheath is largely perpendicular to the plasma-sheath boundary that defines the equipotential surface corresponding to the plasma potential. Because the relative heights of the substrate and surrounding surfaces are fixed for structural and/or for processing reasons, possible radial variations of the sheath voltage drop, and the ensuing variations of the sheath thickness, result in bending of the plasma-sheath boundary. Additionally, the differences in the relative heights of the substrate and the surrounding surfaces may also result in bending of the plasma-sheath boundary even when the sheath thickness is uniform. In turn, the sheath boundary curvature determines ion trajectories, in that the ion trajectories are substantially perpendicular to plasma sheath boundary, resulting in focusing or defocusing of the ions at the edge of the substrate. The net effect depends on whether the sheath voltage and thickness, as well as the heights of the plasma-facing surfaces, decrease or increase with the radius beyond the edge of the substrate, as illustrated in FIGS. 1A and 1C. Note that here and everywhere in this patent application, “at the edge” defines an annular region with the outer/inner radii equal to the radius of the substrate plus/minus a few millimeters (e.g., 3 mm), respectively.

FIG. 1A is a schematic partial cross-sectional view of a device substrate 10 (e.g., portion of a semiconductor substrate) disposed on an electrostatic chuck (ESC) assembly 45 during RIE plasma processing. As schematically shown, the electrostatic chuck assembly 45 generally includes a supporting structure that includes a dielectric containing supporting region 45A that supports an edge ring 40 and a dielectric containing supporting region 45B that supports the substrate 20, which are all supported by a structural element 45C that generally includes a metal baseplate that is coupled to an RF power source. The edge ring 40 is disposed around an outer edge 15 of the device substrate 10. A generated plasma 71 includes a plasma-sheath boundary 75. During processing, ions formed in the plasma 71 pass through the sheath. Depending on the origin of the ions they will have different trajectories 81 that extend from the plasma-sheath boundary 75 to a surface of the device substrate 10 and a surface of the edge ring 40. As was discussed above, the ion trajectories are substantially perpendicular to the plasma sheath boundary, and therefore are determined by the plasma sheath boundary curvature. The device substrate 10 includes a region 11 (FIG. 1B) near the outer edge 15 of the device substrate 10 and a region 12 that is closer to the center of the device substrate 10.

FIG. 1B illustrates a magnified cross-sectional view of the region 11 of the device substrate 10 of FIG. 1A. As shown in FIG. 1B, the device substrate 10 the features in the region 11 include a stop-layer 51 formed over the device substrate 10, one or more device layers 52 formed over the stop-layer 51, and a mask 53 formed over the one or more device layers 52. The RIE plasma process, in which the plasma 71 (FIG. 1A) is generated, is used to remove a portion of the one or more device layers 52 from the device substrate 10 to create a plurality of high aspect ratio structures 91. As will be discussed further below, the angled trajectories 81 of the ions during processing cause the plurality of high aspect ratio structures 91 in the region 11 to be angled. In contrast the plurality of high aspect ratio structures in the region 12 will be substantially vertical.

FIG. 1C is a schematic partial cross-sectional view of a device substrate 20 disposed on the electrostatic chuck assembly 45 during RIE plasma processing. The electrostatic chuck assembly 45 schematically illustrated in FIG. 1C generally includes a supporting structure that includes a dielectric supporting region 45A that supports an edge ring 40′ and a dielectric supporting region 45B that supports the substrate 20, which are all supported by a structural element 45C. The device substrate 20 includes a region 21 (FIG. 1D) near the outer edge 25 of the device substrate 20 and a region 22 that is further from the outer edge 25 of the device substrate 20 than the region 21 is to the outer edge 25 of the device substrate 20. FIG. 1C is similar to FIG. 1A except that the ESC assembly and/or edge ring configuration is different from FIG. 1A, which causes plasma-sheath boundary 76 to have an alternate profile or shape. The device substrate 20 can be substantially similar to the device substrate 10 (i.e., including the same materials, features, and dimensions). The configuration of the edge ring 40′ (e.g., thickness and/or material composition which will have an effect on the impedance of the edge ring 40′) and/or supporting structure of the edge ring (e.g., properties of the dielectric supporting region 45A disposed underneath the edge ring) has altered the profile of the plasma-sheath boundary 76 from the profile shown in FIG. 1A.

FIG. 1D illustrates a cross-sectional view of the region 21 of the device substrate 20. As illustrated in FIG. 1B, the device substrate 20 includes a stop-layer 61 formed over the substrate 60, one or more device layers 62 formed over the stop-layer 61, and a mask 63 formed over the one or more device layers 62. The stop layer 61, the one or more device layers 62, and the mask 63 can be formed of the same materials as the stop layer 51, the one or more device layers 52, and the mask 53, respectively, as illustrated in FIG. 1B. The RIE plasma process, in which the plasma 72 (FIG. 1C) is generated, is used to remove a portion of the one or more device layers 62 from the device substrate 20 to create a plurality of high aspect ratio structures 92. As will be discussed further below, the angled trajectories 82 of the ions during processing cause the plurality of high aspect ratio structures 92 in the region 21 to be angled versus the region 22.

As discussed above, the sheath boundary curvature determines ion trajectories, in that the ion trajectories extending through the sheath are substantially perpendicular to plasma sheath boundary, resulting in focusing or defocusing of the ions at the edge of the substrate. Therefore, by controlling the sheath voltage and thickness radial profiles at the edge of the substrate, one can control the sheath boundary curvature and hence the ion trajectories at the edge of a substrate. Control over ion trajectories at the edge of the substrate is a highly desirable capability, because ion trajectories at the edge affect such process metrics as the critical dimension (CD) bias (which correlates with the blanket etch rate radial profile) and the tilt angle of the features, as shown in FIGS. 1B-1F. Furthermore, independent control over the sheath voltage beyond the edge of the substrate provides an added capability of compensating for downward drift of the surfaces of peripheral components due to wear accumulated over extended periods of time. Namely, for a process with fixed sheath voltage and thickness above the component surrounding the substrate, when this component gets thinner due to wear, the top surface of the component moves downward, along with the plasma-sheath boundary. This downward movement, in turn, changes the curvature of the plasma-sheath boundary and ion trajectories at the edge of the substrate and causes highly undesirable long-term process drifts. However, by increasing the sheath voltage and thickness above the peripheral component in accordance with lowering of the surface, the plasma-sheath boundary can be prevented from drifting downward. This increase in voltage and thickness allows maintaining the pre-defined sheath boundary curvature and ion trajectories at the edge of the substrate and avoiding long-term process drifts. These capabilities, which include (A1) far-edge process tunability and (A2) compensation for downward drifts of the peripheral surfaces due to components wear, do not typically exist in conventional plasma etch tools and special inventive techniques are used in order to achieve such degree of control.

FIGS. 1E and 1F illustrate examples of some additional processing results that can be controlled due to the ability to control and/or adjust the sheath voltage and thickness radial profiles at the edge of the substrate. FIG. 1E is a plot illustrating the effect of adjusting the sheath voltage radial profile on normalized etch rate versus radial position on a substrate, for example, a 300 mm substrate. As illustrated in the example shown in FIG. 1E, by adjusting the sheath voltage radial profile at the edge region of the substrate versus a central region of the substrate the normalized etch rate can be decreased at the edge of the substrate, as shown in curve 36. Alternately, by adjusting the sheath voltage radial profile at an edge region of a substrate versus a central region of the substrate the normalized etch rate can be increased at the substrate edge, as shown in curve 35. Therefore, by adjusting the curvature of the sheath voltage radial profile at the edge region of a substrate will allow the normalized etch rate, and thus the profile of the material etched from the substrate, to be controlled at the edge of the substrate.

FIG. 1F is a plot illustrating the effect of adjusting the sheath voltage radial profile on normalized critical dimension (CD) bias versus radial position on a 300 mm substrate. One will note that CD bias is generally defined by a difference in the critical dimension (CD) of the initial mask image (i.e., pre-etch) and the CD of the final etch pattern (i.e., post-etch). As illustrated in the example shown in FIG. 1F, by adjusting the sheath voltage radial profile at the edge region versus a central region of the substrate the CD bias can be decreased at the substrate edge, as shown in curve 38. Alternately, by adjusting the sheath voltage radial profile at the edge region of a substrate versus a central region of the substrate the CD bias can be increased at the edge, as shown in curve 37. Therefore, by adjusting the curvature of the sheath voltage radial profile at the edge region of a substrate, the CD bias created at the edge of the substrate can be controlled.

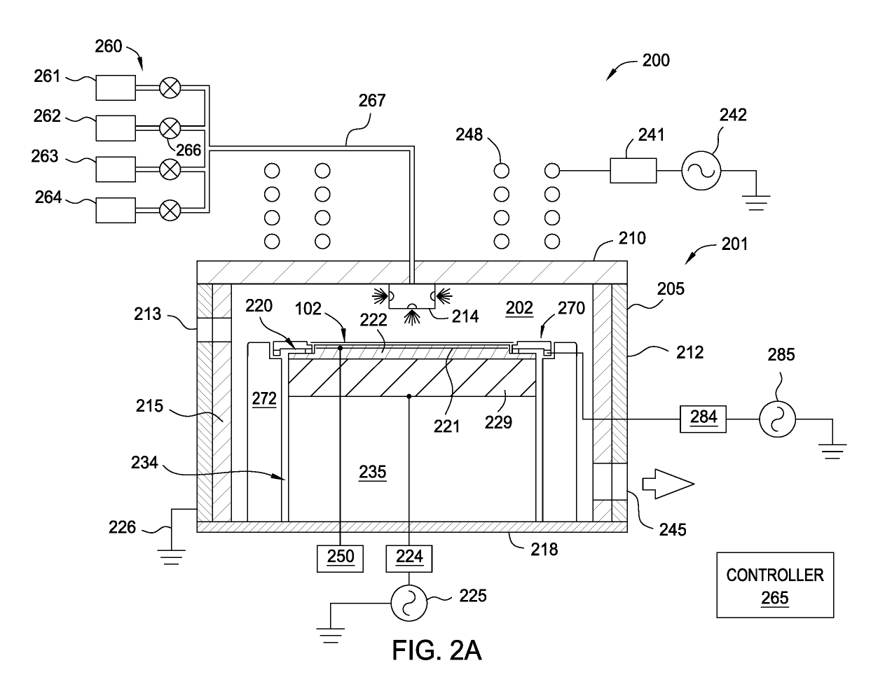

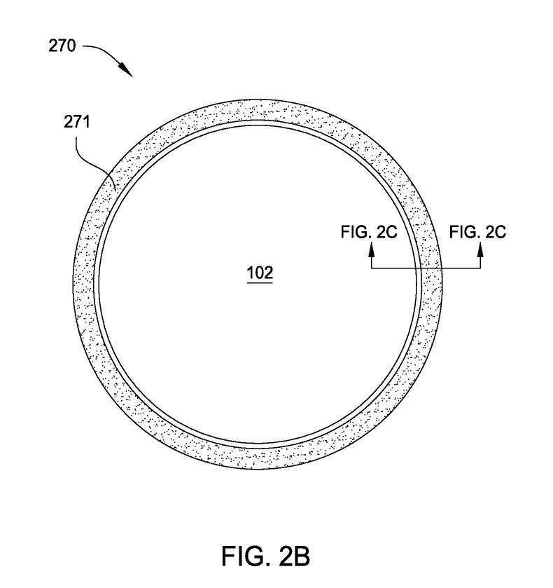

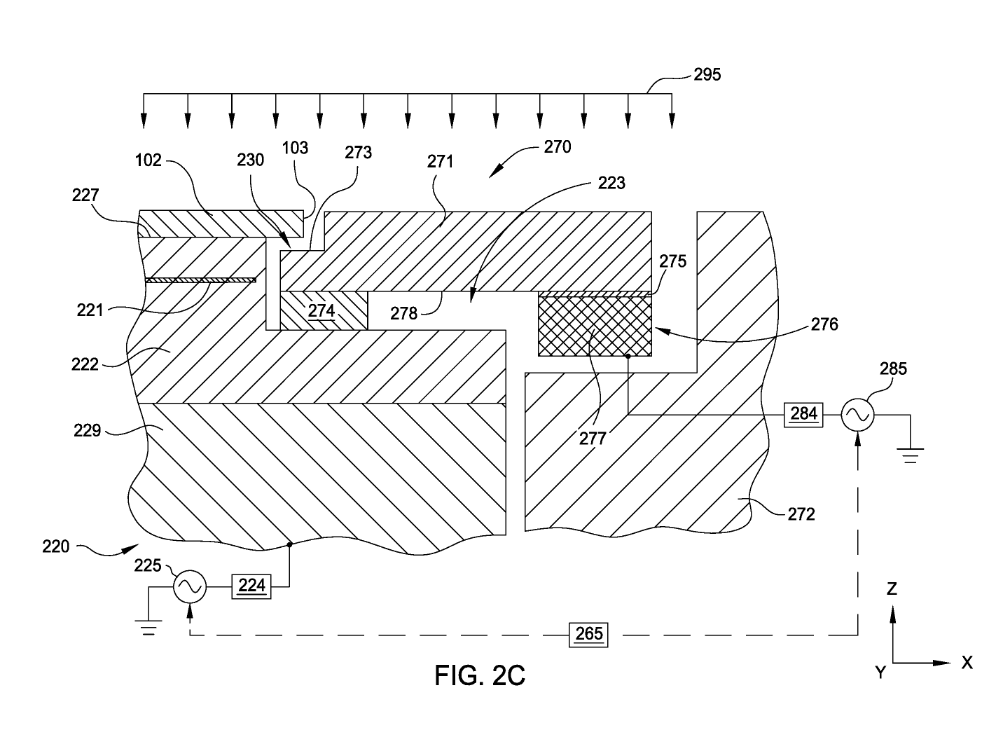

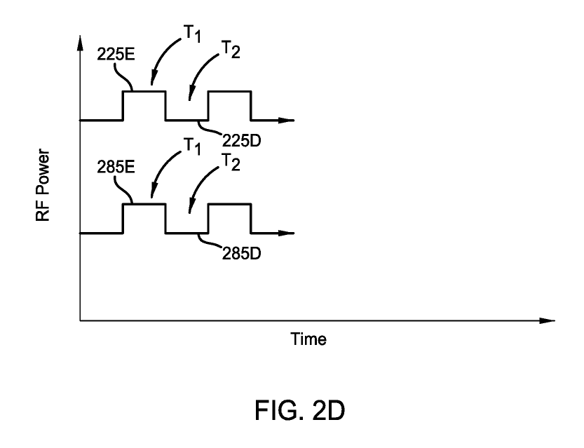

The diameter of the ESC metal baseplate (e.g., element 45C in FIGS. 1A and 1C) and ceramic layer are often made larger than the diameter of the substrate, in which case the portion of the ESC surface extending beyond the substrate is covered with a consumable peripheral component referred to as the “edge-ring” (e.g., edge ring 40 or 40′ in FIGS. 1A and 1C and item 271 in FIGS. 2A-2C). This edge-ring is normally placed directly on the ESC top surface, so it is capacitively coupled to the metal baseplate through the layer of ceramic (e.g., see region 45A) that is typically a few mm thick (for example, 3 mm). In one example, the layer of ceramic may be made from a material such as alumina. Because of the high dielectric constant (e.g. 10) and a relatively small thickness of the ceramic layer, the coupling capacitance is normally quite high (for example, 175-200 pF) and is usually higher than the sheath capacitance (for example, 20-130 pF). The edge-ring is also typically made out of a medium resistivity material, like silicon carbide, to ensure that the resistive impedance of the ring along the axis of the edge ring is significantly smaller than the sheath capacitive-resistive impedance. As a result, there is almost no voltage drop across the ring thickness and all of the RF-voltage capacitively coupled to the ring lower surface drops across the sheath above the ring. Because of the strong capacitive coupling to the metal baseplate and relatively small resistive impedance of the edge-ring along the axis of the edge ring, the ring is effectively RF-powered, similarly to the substrate, in that the RF and DC voltages across the sheath above the ring are comparable to that across the sheath above the substrate.

In order to control the sheath voltage and thickness radial profile across the edge region of the substrate (and hence the sheath boundary curvature) and achieve capabilities A1 and A2, which are discussed above, we propose to: (B1) minimize the coupling capacitance between the edge-ring and the metal baseplate (i.e. decouple the ring from the cathode) in order to considerably decrease or eliminate the cathode-driven RF and DC voltages in the sheath above the edge-ring; and (B2) apply an RF-voltage to the edge-ring from a power source (RF generator), to control the voltage and thickness of the sheath above the edge-ring independently from that above the substrate. In some configurations, the edge-ring can be powered by an RF power source that is separate from the RF power source that is configured to drive the metal base plate disposed under a substrate during processing. In some alternate configurations, the edge-ring and the metal base plate can both be driven in a controlled proportional manner by use of a single RF power source that is coupled to an RF power divider that includes circuitry that is used to provide a controlled proportional amount of power to the edge-ring and the metal base plate. Either of these RF power delivery configurations will allow the control over the curvature of the plasma-sheath boundary and ion trajectories at the edge of the substrate, which in turn yields, at least, the highly desirable added capabilities (A1) and (A2) described above.

FIG. 2A is a simplified cutaway view for an exemplary etching process system 200 including an etching process chamber 201 for performing plasma processing, such as a RIE process, on a device substrate 102 (e.g., a semiconductor device), according to one embodiment.

The etching process chamber 201 includes a chamber body 205 having a process volume 202 defined therein. The chamber body 205 has sidewalls 212 and a bottom 218 which are coupled to an electrical ground 226. The sidewalls 212 have a protective inner liner 215 to extend the time between maintenance cycles of the etching process chamber 201. The dimensions of the chamber body 205 and related components of the etching process chamber 201 are not limited and generally are proportionally larger than the size of the device substrate 102 to be processed therein.

The chamber body 205 supports a chamber lid assembly 210 to enclose the process volume 202. The chamber body 205 may be fabricated from aluminum or other suitable materials. An access port 213 is formed through the sidewalls 212 of the chamber body 205, facilitating the transfer of the device substrate 102 into and out of the etching process chamber 201.

The etching process chamber 201 includes a substrate support assembly 234 that includes a substrate support pedestal 235 and an edge ring assembly 270. The substrate support pedestal 235 is disposed in the process chamber 201 to support the device substrate 102 during processing. The substrate support pedestal 235 can include lift pins (not shown) that can be selectively moved through the substrate support pedestal 235 to lift the device substrate 102 above the substrate support pedestal 235 to facilitate access to the device substrate 102 by a transfer robot (not shown) or other suitable transfer mechanism. In some embodiments, the substrate support pedestal 235 can be surrounded by a quartz pipe 272.

The substrate support pedestal 235 may include an electrostatic chuck (ESC) assembly 220, hereafter ESC 220. The ESC 220 includes a metal baseplate 229 and a dielectric body 222 disposed on the metal baseplate 229. In some embodiments, the dielectric body 222 can be formed of a ceramic and include a chucking electrode 221.

The metal baseplate 229 can be coupled to an RF power source 225 that is integrated with a match circuit 224. The RF power source 225 provides a bias to the metal baseplate 229 which assists in generating the plasma and also attracts plasma ions formed by the process gases in the process volume 202 to the substrate supporting surface of the ESC 220 and the device substrate 102 positioned thereon. The RF power source 225 can supply RF energy at frequencies from about 400 kHz to about 200 MHz, at power levels from about 50 W to about 9000 W. The RF power source 225 can be controlled by a controller 265 included in the etching process system 200. In some embodiments, the RF power supply 225 supplies pulses of RF power to the metal baseplate 229.

The ESC 220 uses electrostatic attraction to hold the device substrate 102 to the substrate support pedestal 235. In some configurations, the electrode 221 in the dielectric body 222 of the ESC 220 is coupled to a DC power source 250. The DC power source 250 can be controlled by the controller 265 for chucking and de-chucking the device substrate 102. Thus, in some cases, the electrode 221 is used to electrostatically hold the device substrate 102 in place during processing.

The ESC 220 may include heater elements (not shown) disposed therein and connected to a heater power source (not shown), for heating the device substrate 102. In some embodiments, a heat transfer base (not shown) can be included in the ESC 220 and can include conduits for circulating a heat transfer fluid to maintain a temperature of the ESC 220 and the device substrate 102 disposed thereon. The ESC 220 is configured to perform in the temperature range demanded by the thermal budget of the device being fabricated on the device substrate 102. For example, the ESC 220 may be configured to maintain the device substrate 102 at a temperature of about minus 20 degrees Celsius to about 90 degrees Celsius for certain embodiments.

The edge ring assembly 270 is disposed on the ESC 220 and around the periphery of the substrate support pedestal 235, so that the edge ring assembly 270 surrounds the device substrate 102 during processing. The edge ring assembly 270 is configured to promote (but not limit to) uniform processing at the edge(s) of the device substrate 102, so that the processing around the edge(s) of the device substrate 102 are consistent with processing across the remainder of the device substrate 102, such as the center of the device substrate 102. Traditionally, edge rings are used to capacitively couple RF energy provided from the metal baseplate 229 to regions in the process volume above the edge ring.

In some embodiments disclosed herein, the edge ring assembly 270 is connected to a separate RF power source 285 to allow the control of the RF bias applied to one or more components within the edge ring assembly 270. In some embodiments, the RF power source 285 is connected to conductive elements within the edge ring assembly 270 through a match circuit 284. The RF power source 285 can supply RF energy at frequencies from about 400 kHz to about 200 MHz, power levels from about 10 W to about 2000 W. The RF power source 285 can be controlled by the controller 265 for controlling the sheath in the process volume 202. The RF power supplied to the edge ring assembly 270 by the RF power source 285 can be adjusted independently from the RF power supplied to the metal baseplate 229 by the RF power source 225 allowing (1) for tuning of the sheath characteristics (such as sheath boundary curvature) over the edge regions of the device substrate 102, and (2) for compensating for wear of the edge ring assembly 270 throughout the useful life of the edge ring assembly 270. In some embodiments, the edge ring assembly 270 can be configured to include temperature control, such as a resistive heater or by flowing a thermal control fluid through a portion of the edge ring assembly. Additional details on the edge ring assembly 270 are described below in reference to FIGS. 2B and 2C below.

The etching process chamber 201 can further include a pumping port 245 formed through one or more of the sidewalls 212 of the chamber body 205. The pumping port is connected to the process volume 202. A pumping device (not shown) is coupled through the pumping port 245 to the process volume 202 to control the pressure therein. The pressure may be controlled during processing between about 1 mTorr to about 200 mTorr.

A gas panel 260 is coupled by a gas line 267 to the chamber body 205 to supply gases into the process volume 202. The gas panel 260 may include one or more process gas sources 261, 262, 263 and may additionally include a dilution gas source 264. Examples of process gases that may be provided by the gas panel 260 include, but are not limited to O₂, N₂, CF₄, CH₂F₂, CHF₃, CL₂, HBr, and SiCL₄. Valves 266 control the flow of the process gases from the gas sources 261, 262, 263, 264 from the gas panel 260 and are managed by a controller 265. The flow of the gases supplied to the process volume 202 from the gas panel 260 may include combinations of the gases.

The chamber lid assembly 210 may include a nozzle 214. The nozzle 214 has one or more ports for introducing the process gases and inert gases from the gas sources 261, 262, 263, 264 of the gas panel 260 into the process volume 202. After the process gases are introduced into the etching process chamber 201, the gases are ionized to form plasma. An antenna 248, such as one or more inductor coils, may be provided adjacent to the etching process chamber 201, such as over the lid assembly 210. An antenna RF power source 242 applies power to the antenna 248 through a match circuit 241 to inductively couple energy, such as RF energy, to the process gas to maintain a plasma formed from the process gas in the process volume 202 of the etching process chamber 201. The RF power source 242 can supply RF energy at frequencies from about 400 kHz to about 200 MHz, at power levels from about 50 W to about 6000 W, The operation of the antenna RF power source 242 may be controlled by a controller, such as the controller 265, that also controls the operation of other components in the etching process chamber 201.

The controller 265 may be utilized to control the process sequence, regulating the gas flows from the gas panel 260 into the etching process chamber 201 and other process parameters, such as the frequencies and power provided to the metal baseplate 229, the edge ring assembly 270, and the antennas 248. The controller 265 is generally designed to facilitate the control and automation of the etching process system 200 and may communicate to the various sensors, actuators, and other equipment associated with the etching process system 200 through wired or wireless connections. The system controller 265 typically includes a central processing unit (CPU) (not shown), memory (not shown), and support circuits (or I/O) (not shown).

The CPU may be one of any form of computer processors that are used in industrial settings for controlling various system functions, substrate movement, chamber processes, and control support hardware (e.g., sensors, internal and external robots, motors, gas flow control, etc.), and monitor the processes performed in the system (e.g., RF power measurements, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU.

The support circuits are also connected to the CPU for supporting the processor in a conventional manner. The support circuits may include cache, power supplies, clock circuits, input/output circuitry, subsystems, and the like. A program (or computer instructions) readable by the controller 265 determines which tasks are performable on a semiconductor device in the etching process chamber 201. Preferably, the program is software readable by the controller 195 that includes code to perform tasks relating to monitoring, execution and control of the movement, support, and/or positioning of a substrate along with the various process recipe tasks (e.g., plasma generation, gas delivery, inspection operations, processing environment controls) and various chamber process recipe operations being performed in the etching process chamber 201. Software routines, when executed by a CPU of the controller 265, transform the CPU into a specific purpose computer (controller) that controls the etching process chamber 201 such that the processes are performed. The software routines may also be stored and/or executed by a second controller (not shown).

FIG. 2B is a top view of the device substrate 102 disposed on the ESC 220 (FIG. 2A) and surrounded by the edge ring assembly 270, according to one embodiment. The edge ring assembly 270 includes an edge ring 271 that surrounds the edge(s) of the device substrate 102 during processing. Additional details on the edge ring 271 and other components of the edge ring assembly 270 are described below in reference to FIG. 2C.

FIG. 2C illustrates one embodiment of the disclosure provided herein, and provides an example of how the ideas (B1) and (B2) discussed above can be implemented. FIG. 2C is a partial cross-sectional view of the device substrate 102, the ESC 220, and the edge ring assembly 270 taken along section line 2C-2C of FIG. 2B. The edge ring assembly 270 includes the edge ring 271 and a plurality of insulating standoffs 274 that are disposed between the edge ring 271 and the dielectric body 222. The dielectric body 222 of the ESC 220 includes an outer ledge 223 that extends around to form an outer perimeter of the dielectric body 222. The outer ledge 223 can be recessed in height relative to a top surface 227 of the dielectric body 222 on which the device substrate 102 is placed on during processing. The insulating standoffs 274 can be disposed on the outer ledge 223. The edge ring 271 can be disposed on the insulating standoffs 274 to electrically decouple the edge ring 271 from portions of the ESC 220 during plasma processing, as per the methods disclosed above in relation to ideas (B1) and (B2). Although only one insulating standoff 274 is shown, a plurality of insulating standoffs 274 can be azimuthally distributed around the outer ledge 223 to introduce a plurality of vacuum gaps between the edge ring 271 and outer ledge 223 region of the dielectric body 222. These vacuum gaps considerably decrease the coupling capacitance formed between the edge ring 271 and ESC 220 due to the small dielectric constant of vacuum (equal to 1) found in the vacuum gaps formed between the insulating standoffs 274. Furthermore, these vacuum gaps can comprise a larger volume than the plurality of insulating standoffs. For example, the standoffs 274 can be evenly distributed around a circumference or other perimeter and the standoffs 274 may only be disposed on 5% or less of that circumference or other perimeter. A reduced footprint of the insulating standoffs 274 can further help to decrease the coupling capacitance formed between the edge ring 271 and portions of the ESC 220.

The dielectric body 222 includes the top surface 227 on which the device substrate 102 is placed on during processing. The device substrate 102 extends past the top surface 227 of the dielectric body 222 of the ESC 220, so that an edge 103 of the device substrate 102 is not contacting the top surface 227 of the dielectric body 222. The edge ring 271 includes an inner ledge 273 that extends under the portion of the device substrate 102 that extends past the top surface 227 of the dielectric body 222 of the ESC 220. The thickness of the insulating standoffs 274 are be selected such that there is still a sufficient vertical gap 230 (for example 0.5 mm) between the top surface of the inner ledge 273 of the edge ring 271 and the bottom surface of the edge 103 of the device substrate 102. This sufficient gap minimizes the capacitive coupling between the edge ring 271 and the device substrate 102, and hence reduce the effect of the RF-power applied to the edge-ring 271 on the sheath above the center region of the device substrate 102.

The edge ring assembly 270 may further include a power distributor 276 and a bonding layer 275. The bonding layer 275 is used to attach the power distributor 276 to a bottom surface 278 of the edge ring 271. The power distributor 276 is connected to a conductor 277, such as an electrically insulated wire. The conductor 277 connects the power distributor 276 to the RF power source 285 (see FIG. 2A). The conductor 277 can be physically coupled (e.g., fixed in place with a metal set-screw) to the power distributor 276. The power distributor 276 can have an annular shape. The power distributor can be formed of a material with a low bulk resistivity, such as material having a resistivity less than 1×10⁻⁷ Ohm-meter (Ω-m), for example aluminum that is anodized.

For a medium-resistivity edge ring 271, the resistance in the azimuthal direction of the edge ring 271 can be quite high (e.g., a few thousand Ohms (k-Ohms)), which may be higher than or comparable to the sheath resistive-capacitive impedance. Therefore, for a medium-resistivity edge ring 271, connecting external RF power from the RF power source 285 directly to the edge ring 271 without using the power distributor 276 could result in significant azimuthal non-uniformities in the sheath voltage and thickness above the edge ring 271. Note that in some embodiments, the use of the power distributor 276 can be circumvented by manufacturing the edge ring 271 out of a material with low resistivity (e.g., <0.5 Ohm-cm), such as highly-doped silicon carbide.

As shown in FIG. 2C, the power distributor 276 is capacitively coupled to the edge ring 271 through the bonding layer 275. In one embodiment, the bonding layer 275 can be a polyimide film, such as Kapton® tape with an adhesive disposed on both sides (e.g., silicone adhesive). The bonding layer 275 can be used to suspend the power distributor 276 from the bottom surface 278 of the edge ring 271. The bonding layer 275 introduces a fairly small capacitive impedance (e.g., 300 Ohm) compared to the sheath capacitive-resistive impedance, which may be, for example, 468-90j Ω for a 1-2 mm thick sheath, and 3424-3045j Ω for a 5-7 mm thick sheath. This fairly small capacitive impedance results in a small to moderate RF-voltage drop (for example, less than 20-25%) compared to the full RF-voltage applied from the external generator. The resistive impedance of the edge ring 271 along the axis of the edge ring 271 (i.e., the Z-direction) is much smaller than the sheath capacitive-resistive impedance. One of the advantages of bonding the power distributor 276 to the edge ring 271 is that it closes any potential vacuum gaps that may be formed between these two components. Note that a vacuum gap as small as 25 microns introduces ˜300 Ohm of effective capacitive impedance (for the entire perimeter of the interface between the power distributor 276 and the edge ring 271), so irregular vacuum gaps can lead to significant azimuthal non-uniformities of the sheath fraction of the applied RF-voltage. Also note that the bonding layer 275 introduce a capacitive impedance uniformly over the perimeter of the interface, so even if the bonding layer 275 incurs a considerable fraction of the applied voltage drop, the desired sheath voltage drop can still be obtained by simply increasing the total applied RF voltage.

In some configurations of the design that may described herein, all of the vacuum gaps between all components are kept small enough to avoid potential arcing (a so-called “plasma light-up”).

Having separate RF power sources 225, 285 connected to the metal baseplate 229 in the ESC 220 and to the edge ring 271, respectively, allows the RF power coupled to the sheath through the edge ring 271 to be independently adjusted relative to the RF power coupled to the sheath through the ESC 220. Thus, the RF power supplied to the edge ring 271 can be adjusted so that the thickness of the sheath above the edge ring 271 substantially matches the thickness of the sheath over the bulk of the ESC 220. Furthermore, because the thickness of the sheath over the edge ring 271 substantially matches the thickness of the sheath over the bulk of the ESC 220, plasma-sheath boundary can be substantially flat, as indicated by plasma-sheath boundaries 295. As discussed above in reference to FIGS. 1A-1D, the ion trajectories towards the substrate are substantially perpendicular to the plasma-sheath boundary. Thus, by coupling the separate RF power source 285 to the edge ring 271 and adjusting the characteristics (e.g., frequency, power level) of the RF power supplied by the RF power source 285, a sheath having a uniform thickness over an entire substrate 102 can be created. Furthermore, the edge regions that would have had angled ion angled trajectories as discussed in reference to FIGS. 1A and 1C can be avoided, and as a consequence production of angled features, such as the angled high aspect ratio structures 91 and 92 of FIGS. 1B and 1D can also be avoided, in cases where these types of formed features are undesirable. In other cases, the production of angled structures can be promoted by coupling the separate RF power source 285 to the edge ring 271 and adjusting the characteristics (e.g., frequency, power level) of the RF power supplied by the RF power source 285. In some embodiments, in which a top surface of the edge ring 271 does not align with a top surface of the device substrate 102 on the ESC, the RF power applied to the edge ring 271 may be adjusted for obtaining a flat plasma-sheath boundary as opposed to a sheath having a uniform thickness over the device substrate 102 and the edge ring 271, so that angled ion trajectories towards the device substrate 102 can be avoided, in cases where these types of formed features are undesirable.

Furthermore, the RF power supplied to the edge ring 271 by the RF power source 285 can be adjusted based on the thickness of the edge ring 271 in the Z-direction and/or based on the height of a top surface 279, so that the thickness of the sheath above the edge ring 271 substantially matches the thickness of the sheath over the bulk of the ESC 220. These adjustments based on the thickness of the edge ring 271 and/or based on the height of the top surface 279 of the edge ring 271 to help compensate for the wear of the edge ring 271 over time to assist in obtaining consistent results throughout the useful life of the edge ring 271.

In some embodiments, the RF power sources 225, 285 can be energized and de-energized at pulse frequencies from about 100 Hz to about 10 kHz, These pulse frequencies can have a duty cycle from about 5% to about 80%. Furthermore, the pulse from the RF power source 285 can be synchronized with the pulse from the RF power source 225 as indicated by pulses 225_{E}, 285_{E} in FIG. 2D both showing an energized state at time T₁ and by pulses 225_{D}, 285_{D} showing a de-energized state at time T₂. In one embodiment, the RF power sources 225, 285 can be configured to operate in a master-slave relationship. For example, the RF power source 285 (slave) coupled to the edge ring 271 can be configured to energize when the RF power source 225 (master) energizes. In this master-slave configuration, the RF power source 285 can receive status of the energized state of the RF power source 225 through the controller 265 (see FIGS. 2A and 2C) or, for example, through a dedicated high-speed controller. Energizing and de-energizing the RF power coupled to the ESC 220 and to the edge ring 271 in a synchronized operation enables efficient control over the sheath boundary curvature and hence the ion trajectories at the edge of the device substrate 102.

In another embodiment, the RF power source 225 and the RF power source 285 can operate in phase at a same RF frequency. In such an embodiment, the phase of the RF signal supplied by the RF power source 285 can be phase-locked with the phase of the RF signal supplied by the RF power source 225. In a phase-locked embodiment, the power level of the RF power provided by the RF power source 285 can still be independently adjusted relative to the power level of the RF power provided by the RF power source 225.

In some embodiments, it may be desirable for the RF signals supplied to the metal baseplate 229 in the ESC 220 and to the edge ring 271 to operate at a same RF frequency. In another embodiment, it may be desirable to use a single RF power source to supply RF power to the metal baseplate 229 in the ESC 220 and to the edge ring 271. Using a single RF power source can ensure that the phase and frequency of the RF signal applied to the metal baseplate 229 in the ESC 220 and to the edge ring 271 is the same. Even though a single RF power source may be used in such embodiments, the RF power of the RF signal supplied to the metal baseplate 229 in the ESC 220 can still be independently adjusted relative to the RF power provided to the edge ring 271 by the proportional delivery of RF power provided from a single RF source.

Although controlling the sheath thickness and flatness of the plasma-sheath boundary is largely described in terms of adjusting the RF power applied to the edge ring 271 while maintaining the characteristics of the RF power applied to the metal baseplate 229 of the ESC 220, it is also possible to adjust the RF power applied to the metal baseplate 229 of the ESC 220 while maintaining the characteristics of the RF power applied to the edge ring 271. Having the RF power applied to the edge ring 271 be independent of the RF power applied to the metal baseplate 229 of the ESC 220 allows for the control of the sheath thickness and flatness of the plasma-sheath boundary.

In some embodiments of the method(s) provided herein, the plasma formed within the processing volume 202 of the process chamber 201 may be generated by applying RF power to the antenna 248 and also simultaneously applying RF power to the edge ring 271 from a separate RF power source (e.g., RF power source 285). In this case, it may be possible to assist the antenna 248 in the initiation of the generated plasma by the additional RF power supplied by an RF signal supplied to the edge ring 271. Assisting in the generation of the plasma by delivering RF power to the edge ring 271, along with the RF power applied to the antenna 248, can help improve the reliability of the formation of the plasma in the processing volume of some types of processing chambers (e.g., inductively coupled plasma processing chambers) and/or also possibly reducing the variability in the time it takes to initiate the plasma within a process chamber.

While the foregoing is directed to embodiments of the present disclosure, other and further embodiments of the disclosure may be devised without departing from the basic scope thereof, and the scope thereof is determined by the claims that follow.

1. A substrate support assembly comprising:
an electrostatic chuck assembly comprising an electrode, wherein the electrode is electrically connected to a first RF power source;
an edge ring disposed around the electrostatic chuck assembly; and
a distributor attached to a surface of the edge ring, wherein the distributor is directly connected to a second RF power source.

2. The substrate support assembly of claim 1, further comprising a plurality of insulating standoffs disposed between the electrostatic chuck assembly and the edge ring, wherein the insulating standoffs are spaced apart from each other to form a plurality of gaps between the electrostatic chuck assembly and the edge ring.

3. The substrate support assembly of claim 2, wherein the plurality of gaps comprises a larger volume than the plurality of insulating standoffs.

4. The substrate support assembly of claim 1, wherein the distributor is attached to the surface of the edge ring by a bonding layer configured to capacitively couple the RF power from the second RF power source through the edge ring.

5. The substrate support assembly of claim 4, wherein the bonding layer is a double-side adhesive tape.

6. The substrate support assembly of claim 1, wherein the distributor has a resistivity less than 1×10⁻⁷ ohm-m.

7. The substrate support assembly of claim 6, wherein the distributor has an annular shape.

8. A plasma processing system, comprising:
an RF power source assembly comprising:
a first RF power source; and
a second RF power source; and
a substrate support assembly, comprising;
an electrostatic chuck assembly comprising an electrode, wherein the electrode is electrically connected to the first RF power source; and
an edge ring disposed around the electrostatic chuck assembly, wherein the edge ring is electrically connected to the second RF power source.

9. The plasma processing system of claim 8, wherein the edge ring has a resistivity of <0.5 Ohm-cm.

10. The plasma processing system of claim 9, further comprising a plurality of insulating standoffs disposed between the electrostatic chuck assembly and the edge ring, wherein the insulating standoffs are spaced apart from each other to form a plurality of gaps between the electrostatic chuck assembly and the edge ring.

11. The plasma processing system of claim 10, wherein the plurality of gaps comprises a larger volume than the plurality of insulating standoffs.

12. The plasma processing system of claim 8, further comprising
a third RF power source; and
one or more coils disposed over the substrate support assembly, wherein the one or more coils are electrically coupled to the third RF power source.

13. The plasma processing system of claim 12, further comprising a controller coupled to the first RF power source, the second RF power source and the third RF power source, wherein the controller is configured to initiate a plasma over the substrate support assembly by energizing the second RF power source without energizing the first RF power source.

14. The plasma processing system of claim 8, further comprising a controller coupled to the first RF power source and the second RF power source, wherein the controller is configured to:
operate first RF power source and the second RF power source at a first pulse frequency; and
synchronize pulses of RF energy supplied to the electrode and to the edge ring at the first pulse frequency.

15. The plasma processing system of claim 8, wherein the RF power source assembly further comprises a single RF power source that is coupled to a power divider assembly, wherein the first RF power source and the second RF power source are each separate RF power delivery components disposed within the power divider assembly.

16. A method of processing a substrate comprising:
supplying one or more gases to a process volume of a plasma chamber, wherein
a first electrode is positioned to provide electromagnetic energy to the process volume when RF power is provided to the first electrode;
a first substrate is disposed on an electrostatic chuck assembly that is disposed within the process volume,
the electrostatic chuck assembly includes an electrode, and
an edge ring is disposed around the electrostatic chuck assembly;
generating a plasma of the one or more gases in the process volume of the plasma chamber by energizing a first RF power source electrically connected to the first electrode; and
etching a portion of the first substrate by energizing a second RF power source electrically connected to the edge ring and energizing a third RF power source electrically connected to the electrode of the electrostatic chuck assembly after generating the plasma.

17. The method of claim 16, wherein
the first electrode comprises one or more coils disposed outside of the process volume, and
the first RF power source and the second RF power source are energized at a first pulse frequency that synchronizes an RF signal from the first RF power source with an RF signal from the second RF power source.

18. The method of claim 16, wherein the plasma is initially generated by simultaneously energizing the first RF power source and the second RF power source.

19. The method of claim 16, further comprising:
removing the first substrate from the process volume of the plasma chamber after etching the portion of the first substrate;
positioning a second substrate on the electrostatic chuck assembly in the process volume of the plasma chamber after the removal of the first substrate;
supplying the one or more gases to a process volume of a plasma chamber; and
generating a plasma of the one or more gases over the second substrate by energizing the first RF power source electrically connected to the first electrode; and
etching at least a portion of the second substrate, wherein etching at least a portion of the second substrate comprises
energizing the second RF power source electrically connected to the edge ring; and
energizing the third RF power source electrically connected to the electrode of the electrostatic chuck assembly after generating the plasma,
wherein one or more of the RF characteristics of an RF signal supplied from the second RF power source during the etching of the second substrate are adjusted relative to the RF characteristics of the RF signal supplied from the second RF power source during the etching of the first substrate based on a change in a characteristic of the edge ring.

20. The method of claim 19, wherein the characteristic of the edge ring comprises a change in thickness of the edge ring.
